(19) United States
(12) Patent Application Publication
(10) Pub. No.: US 2021/0288116 A1
(43) Pub. Date: Sep. 16, 2021

(54) COLOR FILTER SUBSTRATE AND MANUFACTURING METHOD THEREOF, AND ORGANIC LIGHT-EMITTING DIODE (OLED) DISPLAY PANEL

(71) Applicant: Shenzhen CHina Star Optoelectronics Display Technology Co., LTD., Shenzhen, Guangdong (CN)

(72) Inventor: Ming XU, Shenzhen, Guangdong (CN)

(21) Appl. No.: 16/766,688

(22) PCT Filed: Apr. 2, 2020
(86) PCT No.: PCT/CN2020/083078

§ 371 Date: May 24, 2020

(30) Foreign Application Priority Data
Mar. 11, 2020 (CN) 202010165497.8

(51) Int. Cl. H01L 27/32; H01L 51/52

(52) U.S. Cl. CPC H01L 27/322; H01L 51/5268; H01L 27/3244; H01L 51/5265; H01L 51/5253; H01L 51/5284

(57) ABSTRACT

A color filter substrate, including a color filter base, as well as a black matrix and a plurality of color resists which are disposed on the color filter base, wherein the plurality of color resists are disposed at intervals with the black matrix, and each of the color resists has a wrinkled surface to increase a light scattering angle. By forming the plurality of color resists with the wrinkled surfaces on the color filter substrate, not only will the organic light-emitting diode display panel with a microcavity structure be able to perform with high color gamut and high brightness, viewing angles of the display panel are also improved.

### TECHNICAL FIELD

The present application relates to the display technology field, and more particularly, to a color filter substrate and a manufacturing method thereof, and an organic light-emitting (OLED) diode display panel capable of improving viewing angles of a display panel.

### BACKGROUND

With development of display panels, in order to achieve a more striking visual impact, high color gamut and wide viewing angles have become necessities for the panels. In order to meet a requirement of high color gamut, a microcavity structure is usually adopt by organic light-emitting diode display panels, which allows redistribution of a light field, changes quantum efficiency, and narrows spectrum, thereby making emitted light become stronger forward light with higher color purity.

However, viewing angles of the display panels become worse as intensity of a microcavity effect increases. Therefore, it is necessary to provide a color filter substrate and a manufacturing method thereof, and an organic light-emitting (OLED) diode display panel to solve a problem that the viewing angles of the display panels cannot be effectively improved while maintaining high color gamut in the prior art.

### Technical Problem

An objective of the present invention is to provide a color filter substrate and a manufacturing method thereof, and an organic light-emitting (OLED) diode display panel to improve viewing angles of the display panels and solve a problem in the prior art.

### Technical Solution

To achieve above objective, a first aspect of the present invention provides a color filter substrate, comprising:
a color filter base, on which a black matrix disposed; and
a plurality of color resists, disposed on the color filter base at intervals with the black matrix,
wherein each of the color resists has a wrinkled surface to increase a light scattering angle.

Further, a height of the black matrix is greater than a height of the plurality of color resists.

Further, the black matrix has a bottom surface and a top surface, the bottom surface of the black matrix is in contact with a surface of the color filter base, and a width of the bottom surface of the black matrix is greater than a width of the top surface of the black matrix.

Further, the black matrix has a bottom surface and a top surface, the bottom surface of the black matrix is in contact with a surface of the color filter base, and a width of the bottom surface of the black matrix is less than a width of the top surface of the black matrix.

A second aspect of the present invention provides a method for manufacturing a color filter substrate, comprising following steps:
forming a black matrix on a color filter base;
forming a plurality of color resists with wrinkled surfaces on the color filter base, and disposing the plurality of color resists between adjacent black matrixes; and
repeating above steps to form color resists of different colors between the adjacent black matrixes.

Further, forming the plurality of color resists with wrinkled surfaces comprises:
coating a color resist material on the color filter base, and heating the color filter base and the color resist material;
cooling the color filter base and the color resist material; and
performing photolithography and etching processes on the color resist material to obtain the plurality of color resists with the wrinkled surfaces.

Further, a height of the black matrix is greater than a height of the plurality of color resists.

Further, the black matrix has a bottom surface and a top surface, the bottom surface of the black matrix is in contact with a surface of the color filter base, and a width of the bottom surface of the black matrix is greater than a width of the top surface of the black matrix.

Further, the black matrix has a bottom surface and a top surface, the bottom surface of the black matrix is in contact with a surface of the color filter base, and a width of the bottom surface of the black matrix is less than a width of the top surface of the black matrix.

Further, heating the color filter base and the color resist material is performed at a temperature ranged from 200° C. to 300° C., and a heating duration ranged from 5 minutes to 30 minutes.

Further, the color filter base and the color resist material are cooled down to 10° C. to 20° C. or cooled down at room temperature.

A third aspect of the present invention provides an organic light-emitting diode (OLED) display panel, comprising:
an OLED device, comprising a thin film transistor device and an organic light emitting layer, the organic light emitting layer configured to emit light; and
a color filter substrate, disposed opposite to the thin film transistor device, comprising a plurality of color resists and a black matrix, the plurality of color resists disposed on a color filter base at intervals with the black matrix, and each of the plurality of color resists has a wrinkled surface facing the thin film transistor device to increase a light scattering angle emitted by the organic light emitting layer.

Further, a height of the black matrix is greater than a height of the plurality of color resists.

Further, the black matrix has a bottom surface and a top surface, the bottom surface of the black matrix is in contact with a surface of the color filter base, and a width of the bottom surface of the black matrix is greater than a width of the top surface of the black matrix.

Further, the black matrix has a bottom surface and a top surface, the bottom surface of the black matrix is in contact with a surface of the color filter base, and a width of the bottom surface of the black matrix is less than a width of the top surface of the black matrix.

Further, the plurality of color resists comprise red color resists, green color resists, and blue color resists that are disposed corresponding to different colors of light emitted by the organic light emitting layer, respectively.

Further, the OLED display panel further comprises an anode electrode and a cathode electrode, the organic light emitting layer is connected to a drain electrode of the thin film transistor layer through the anode electrode, the cathode electrode is disposed at another end of the organic light emitting layer, and the anode electrode and the cathode electrode are used to apply a bias voltage to the organic light emitting layer.

Further, the anode electrode is composed of a metal material with high reflectivity, and the cathode electrode is composed of a transparent conductive thin film with light transmittance.

Further, a Bragg reflector mirror is disposed in the organic light emitting layer to enhance a microcavity effect.

Further, the OLED display panel further comprises an encapsulation layer disposed between the organic light emitting layer and the color filter substrate to prevent water and oxygen from intruding the organic light emitting layer.

### Beneficial Effect

According to the present invention, by forming a plurality of color resists with wrinkled surfaces on a color filter substrate, not only will an organic light-emitting diode (OLED) display panel with a microcavity structure be able to perform with high color gamut and high brightness, a problem of worse viewing angles caused by a microcavity effect is also solved, thereby improving viewing angles of the display panel. Furthermore, the color filter substrate is located outside the OLED device, and does not affect its own electrical properties. It can be seen that the present invention is nonobvious.

### DESCRIPTION OF DRAWINGS

FIG. 1 is a schematic diagram showing an organic light-emitting diode (OLED) display panel according to an embodiment of the present application.

FIG. 2 is a schematic diagram showing a color filter substrate with a high black matrix according an embodiment of the present application.

FIG. 3 is a step diagram of a method for manufacturing the color filter substrate according to an embodiment of the present application.

FIG. 4 is a step diagram of a method for manufacturing a plurality of color resists with wrinkled surfaces according to an embodiment of the present application.

FIGS. 5A-5C are flowcharts of the method for manufacturing the plurality of color resists with the wrinkled surfaces according to an embodiment of the present application.

### DETAILED DESCRIPTION OF PREFERRED EMBODIMENTS

To make objectives, technical schemes, and effects of the present invention clearer and more specific, the present invention is described in further detail below with reference to appending drawings. It should be understood that specific embodiments described herein are merely for explaining the present invention, and are not intended to limit the present invention.

Following descriptions for respective embodiments are embodiments capable of being implemented for illustrating the present invention with reference to the appending drawings. Spatial terms mentioned in the present invention are only directions with reference to the appending drawings. Therefore, the spatial terms used are merely for describing and understanding the present invention, it is not intended to limit the present invention.

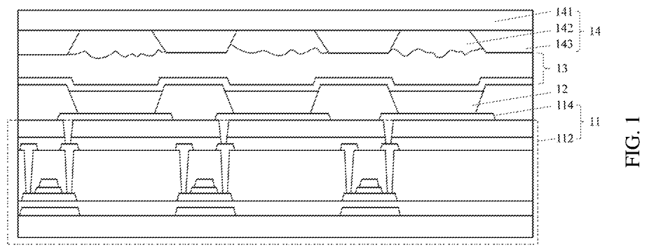

Referring to FIG. 1, which is a schematic diagram showing an organic light-emitting diode (OLED) display panel according to an embodiment of the present application. The organic light-emitting diode display panel includes an organic light-emitting diode device and a color filter substrate 14, wherein the organic light-emitting diode device is a light-emitting device, which includes a thin film transistor device 11, an organic light-emitting layer 12, and an encapsulation layer 13. The thin film transistor device 11 is used to control a light-emitting display of the OLED display panel, which includes a thin film transistor (TFT) layer 112 and an anode electrode 114, wherein the thin film transistor layer 112 may have a top-gate structure, a bottom-gate structure, or a dual-gate structure, etc., types of the thin film transistor layer 112 are not further limited by the present invention. One end of the anode electrode 114 is electrically connected to a drain electrode (unmarked) of the thin film transistor layer 112, and another end is electrically connected to the organic light-emitting layer 12. In the embodiment of the present invention, the organic light-emitting layer 12 is further sequentially formed with a hole injection layer (not shown), a hole transport layer (not shown), a photoluminescent layer (not shown), an electron transport layer (not shown), an electron injection layer (not shown), and a cathode electrode (not shown) on the anode electrode 114. By applying a bias to the anode electrode 114 and the cathode electrode, electrons in the electron injection layer and holes in the hole injection layer respectively pass through the electron transport layer and the hole transport layer to generate excitations in the photoluminescent layer to emit light. It can be understood that colors of light emitted by the photoluminescent layer will depend on a material of the photoluminescent layer. For example, if the material of the photoluminescent layer is PTPP or DCJTB, etc., it emits red light, if the material is Alaq3 or TDETE, etc., it emits green light, and if the material is TMTPEPA or BDPAS, etc., it emits blue light. The material of the photoluminescent layer is not further limited by the present invention.

In the embodiment of the present invention, a top-emission OLED display panel is used as an example for the present invention. Therefore, the anode electrode 114 is composed of a metal material with high reflectivity (such as metallic copper), and the cathode electrode is composed of a transparent conductive thin film with light transmittance (such as indium-tin-oxide). Whether it is a top-emission or bottom-emission OLED display panel, both of them is a structure formed by one total-reflection surface (i.e. metal material) and one semi-reflection surface (i.e. transparent conductive thin film) parallel to each other, and they all have a considerable microcavity effect. That is, a micro-resonant cavity is formed between the total-reflection surface and the semi-reflection surface, so that light emitted by the photoluminescent layer will be reflected back and forth in the micro-resonance cavity multiple times and improve, and only light with a specific wavelength that resonates with the micro-resonant cavity can be emitted at a specific angle, so full width at half maximum (FWHM) of emitted light will be narrower, and the energy of emitted light will be stronger, thereby improving a performance on color gamut and brightness of the display panel. In an embodiment, a distributed Bragg reflector (DBR) mirror can be disposed in the organic light-emitting layer 12 to enhance the microcavity effect. However, although the performance of the display can be improved by the microcavity effect, it also causes a phenomenon that viewing angles of the display panel deteriorate. Therefore, the viewing angles of the display panel are improved by forming a plurality of color resists with wrinkled surfaces on the color filter substrate 14 according to the present invention.

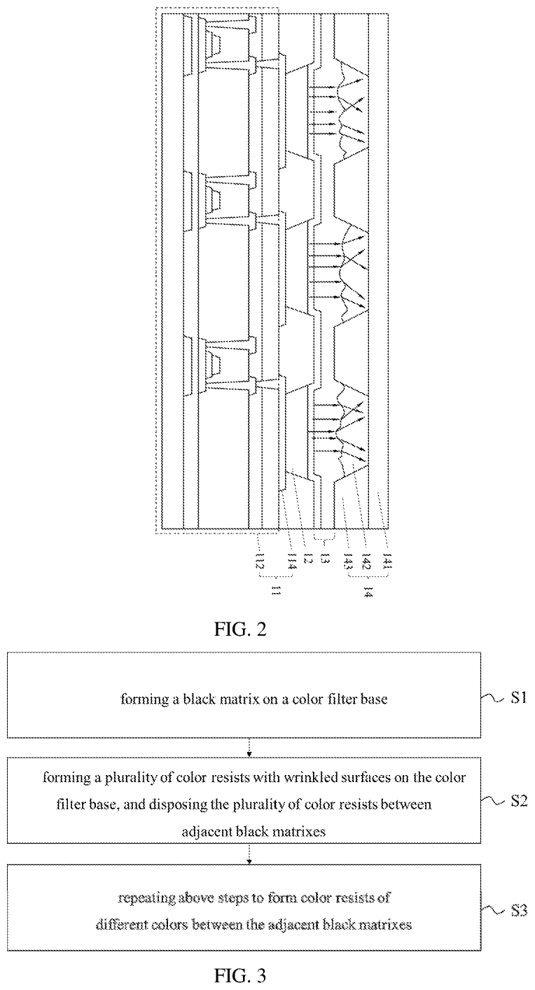

Specifically, after forming an encapsulation layer 13 on the organic light-emitting layer 12 to prevent water and oxygen from intruding the organic light-emitting layer 12, a color filter substrate 14 is formed on the encapsulation layer 13 and formed opposite to the thin film transistor device 11. The color filter substrate 14 includes a color filter base 141, as well as the plurality of color resists 142 and a black matrix 143 which are formed on the color filter base 141 facing the thin film transistor device 11, wherein the plurality of color resists 142 are disposed at intervals with the black matrix 143. The plurality of color resists 142 include red color resists, green color resists, and blue color resists, and they are respectively disposed corresponding to colors of light emitted by the organic light-emitting layer 12, that is, the red color resists are disposed corresponding to red light emitted by the organic light-emitting layer 12, the green color resists are disposed corresponding to emitted green light, and the blue color resists are disposed corresponding to emitted blue light. An objective of forming the wrinkled surface on each of the plurality of color resists 142 is to improve a light scattering angle when light passes through these wrinkled surfaces, that is, light will be scattered due to an irregular shape of the wrinkled surface, and an scattering angle becomes wider, thereby improving the viewing angles of the OLED display panel. Furthermore, in order to prevent interferences between adjacent scattered light, a height of the black matrix 143 may be greater than heights of the plurality of color resists 142, as shown in FIG. 2.

In conjunction with FIG. 3, which is a step diagram of a method for manufacturing the color filter substrate according to an embodiment of the present application. The method includes steps of:

Step S1: forming a black matrix 143 on a color filter base 141.

In this step, since the black matrix 143 with a greater height can be formed to prevent interferences between adjacent scattered light, it may generate a taper during photolithography and etching processes, so that a width of a bottom surface of the black matrix 143 is greater than a width of a top surface of the black matrix 143, wherein the bottom surface of the black matrix 143 is in contact with a surface of the color filter base 141. It can be understood that the black matrix 143 may have different shapes due to different manufacturing methods, so in another embodiment, the width of the bottom surface may be less than the width of the top surface of the black matrix 143.

Step S2: forming a plurality of color resists with wrinkled surfaces on the color filter base 141, and disposing the plurality of color resists between adjacent black matrixes.

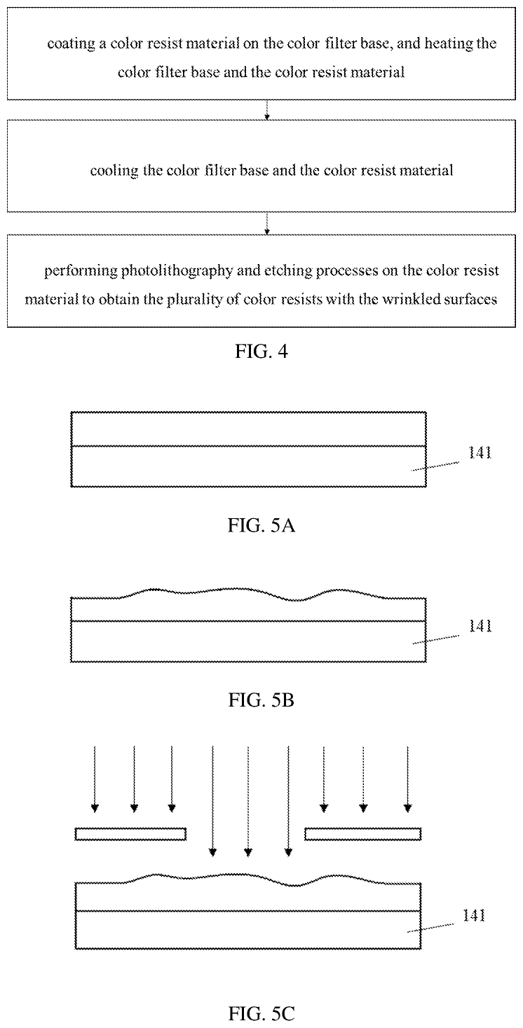

In conjunction with FIG. 4 and FIGS. 5A-5C, FIG. 4 is a step diagram of a method for manufacturing the plurality of color resists 142 with the wrinkled surfaces according to an embodiment of the present application, FIGS. 5A-5C are flowcharts of the method for manufacturing the plurality of color resists with the wrinkled surfaces according to an embodiment of the present application. In this step, first, a color resist material is coated on the color filter base 141 (as shown in FIG. 5A), and the color filter base 141 and the color resist material are heated, a heating temperature and a heating duration need to be controlled within a range so that quality of the color resist material will not be changed. For example, the heating temperature may be controlled in a range from 200° C. to 300° C., and the heating duration ranges from 5 minutes to 30 minutes. Then, the color filter base 141 and the color resist material are cooled down to 10° C. to 20° C. or cooled down at room temperature, and a surface of the color resist material is wrinkled (as shown in FIG. 5B), then photolithography and etching processes are performed on the color resist material (as shown in FIG. 5C) to obtain the plurality of color resists 142 with the wrinkled surfaces. A reason for the formation of the wrinkled surfaces is that the color resist material and the color filter base 141 have different thermal expansion coefficients, so that the color resist material deforms after heating and cooling to form irregular wrinkle shapes.

Step S3: repeating above steps to form color resists of different colors between the adjacent black matrixes.

The color filter substrate 14 described in the present invention may be further applied to other types of display panels, such as a liquid crystal display (LCD) panel or a quantum dot light emitting diode (QLED) display panel.

In summary, according to the present invention, by forming the plurality of color resists with the wrinkled surfaces on the color filter substrate, not only will the OLED display panel with the microcavity structure be able to perform with high color gamut and high brightness, a problem of worse viewing angles caused by the microcavity effect is also solved, thereby improving the viewing angles of the display panel. Furthermore, the color filter substrate is located outside the OLED device, and does not affect its own electrical properties.

Above all, although the present application has been disclosed above in the preferred embodiments, the above preferred embodiments are not intended to limit the present application. For persons skilled in this art, various modifications and alterations can be made without departing from the spirit and scope of the present application. The protective scope of the present application is subject to the scope as defined in the claims.

1. A color filter substrate, comprising:
a color filter base, on which a black matrix disposed; and
a plurality of color resists, disposed on the color filter base at intervals with the black matrix,
wherein each of the color resists has a wrinkled surface to increase a light scattering angle.

2. The color filter substrate as claimed in claim 1, wherein a height of the black matrix is greater than a height of the plurality of color resists.

3. The color filter substrate as claimed in claim 1, wherein the black matrix has a bottom surface and a top surface, the bottom surface of the black matrix is in contact with a surface of the color filter base, and a width of the bottom surface of the black matrix is greater than a width of the top surface of the black matrix.

4. The color filter substrate as claimed in claim 1, wherein the black matrix has a bottom surface and a top surface, the bottom surface of the black matrix is in contact with a surface of the color filter base, and a width of the bottom surface of the black matrix is less than a width of the top surface of the black matrix.

5. A method for manufacturing a color filter substrate, comprising following steps:
forming a black matrix on a color filter base;
forming a plurality of color resists with wrinkled surfaces on the color filter base, and disposing the plurality of color resists between adjacent black matrixes; and
repeating above steps to form color resists of different colors between the adjacent black matrixes.

6. The method as claimed in claim 5, wherein forming the plurality of color resists with wrinkled surfaces comprises:
coating a color resist material on the color filter base, and heating the color filter base and the color resist material;
cooling the color filter base and the color resist material; and
performing photolithography and etching processes on the color resist material to obtain the plurality of color resists with the wrinkled surfaces.

7. The method as claimed in claim 5, wherein a height of the black matrix is greater than a height of the plurality of color resists.

8. The method as claimed in claim 5, wherein the black matrix has a bottom surface and a top surface, the bottom surface of the black matrix is in contact with a surface of the color filter base, and a width of the bottom surface of the black matrix is greater than a width of the top surface of the black matrix.

9. The method as claimed in claim 5, wherein the black matrix has a bottom surface and a top surface, the bottom surface of the black matrix is in contact with a surface of the color filter base, and a width of the bottom surface of the black matrix is less than a width of the top surface of the black matrix.

10. The method as claimed in claim 6, wherein heating the color filter base and the color resist material is performed at a temperature ranged from 200° C. to 300° C., and with a heating duration ranged from 5 minutes to 30 minutes.

11. The method as claimed in claim 6, wherein the color filter base and the color resist material are cooled down to 10° C. to 20° C. or cooled down at room temperature.

12. A organic light-emitting diode (OLED) display panel, comprising:
an OLED device, comprising a thin film transistor device and an organic light emitting layer, the organic light emitting layer configured to emit light; and
a color filter substrate, disposed opposite to the thin film transistor device, comprising a plurality of color resists and a black matrix, the plurality of color resists disposed on a color filter base at intervals with the black matrix, and each of the plurality of color resists has a wrinkled surface facing the thin film transistor device to increase a light scattering angle emitted by the organic light emitting layer.

13. The OLED display panel as claimed in claim 12, wherein a height of the black matrix is greater than a height of the plurality of color resists.

14. The OLED display panel as claimed in claim 12, wherein the black matrix has a bottom surface and a top surface, the bottom surface of the black matrix is in contact with a surface of the color filter base, and a width of the bottom surface of the black matrix is greater than a width of the top surface of the black matrix.

15. The OLED display panel as claimed in claim 12, wherein the black matrix has a bottom surface and a top surface, the bottom surface of the black matrix is in contact with a surface of the color filter base, and a width of the bottom surface of the black matrix is less than a width of the top surface of the black matrix.

16. The OLED display panel as claimed in claim 12, wherein the plurality of color resists comprise red color resists, green color resists, and blue color resists that are disposed corresponding to different colors of light emitted by the organic light emitting layer, respectively.

17. The OLED display panel as claimed in claim 12, wherein the OLED display panel further comprises an anode electrode and a cathode electrode, the organic light emitting layer is connected to a drain electrode of the thin film transistor device through the anode electrode, the cathode electrode is disposed at another end of the organic light emitting layer, and the anode electrode and the cathode electrode are used to apply a bias voltage to the organic light emitting layer.

18. The OLED display panel as claimed in claim 17, wherein the anode electrode is composed of a metal material with high reflectivity, and the cathode electrode is composed of a transparent conductive thin film with light transmittance.

19. The OLED display panel as claimed in claim 12, wherein a Bragg reflector mirror is disposed in the organic light emitting layer to enhance a microcavity effect.

20. The OLED display panel as claimed in claim 12, wherein the OLED display panel further comprises an encapsulation layer disposed between the organic light emitting layer and the color filter substrate to prevent water and oxygen from intruding the organic light emitting layer.
